(19) United States
(12) Patent Application Publication
(10) Pub. No.: US 2014/0199949 A1
(43) Pub. Date: Jul. 17, 2014

(54) METHOD FOR IMPROVING TX GAIN IN ENVELOPE TRACKING SYSTEMS

(71) Applicant: MOTOROLA MOBILITY LLC, Libertyville, IL (US)

(72) Inventors: Thomas D. Nagode, Vernon HIlls, IL (US); Gregory R. Black, Vernon Hills, IL (US); Ryan J. Goedken, Santa Clara, CA (US)

(73) Assignee: MOTOROLA MOBILITY LLC, Libertyville, IL (US)

(21) Appl. No.: 13/742,850

(22) Filed: Jan. 16, 2013

(51) Int. Cl. H04B 1/62; H03G 3/00

(52) U.S. Cl. CPC H04B 1/62; H03G 3/00
USPC 455/73; 330/129

(57) ABSTRACT

A method and system enhances the gain of a propagation path of a radio frequency (RF) signal while utilizing an envelope tracking (ET) mechanism to provide power to a power amplifier within the propagation path. An envelope tracking (ET) controller detects using the ET mechanism an RF envelope of the RF signal being propagated towards the power amplifier. The ET controller applies envelope pre-distortion to the RF signal. The ET controller initiates a function for shaping the supply voltage of the power amplifier by selecting a shaping table that can provide a specific level of increasing amplifier gain at higher signal drive level. The ET controller shapes the supply voltage for the power amplifier by adjusting values corresponding to the detected RF envelope. As a result, RF signals are propagated from the transceiver to the power amplifier output port across high and low transceiver drive levels with net constant gain.

### BACKGROUND

1. Technical Field

The present disclosure relates in general to wireless communication devices and in particular to power amplifiers in wireless communication devices.

2. Description of the Related Art

Envelope Tracking (ET) is a method of improving power amplifier (PA) efficiency by dynamically varying the supply voltage to the PA in accordance with the radio frequency (RF) envelope. Radio access technologies such as code division multiple access (CDMA), wideband CDMA (WCDMA), and Long Term Evolution (LTE) have amplitude modulation with up to 8 dB peak to average ratio (PAR). This level of PAR indicates that most of the time, the PA's average transmit power is much lower than the peak power, and PA efficiency is degraded. Envelope tracking reduces the supply voltage when amplitude modulation (AM) is not at its peak, to recover PA efficiency and, as a result, improves current drain and heating performance.

The gain of the PA varies with PA supply voltage as the PA supply voltage is being modulated by the RF envelop. A shaping table is used to shape the supply voltage with RF envelope to achieve constant gain across the relevant transceiver drive levels. Unfortunately the PA gain may be reduced by ˜2.0 dB and requires a corresponding drive level increase. This can be done by increasing the gain of the driver stages on the PA or by increasing the driver requirements of the transceiver causing increased power consumption. However, both of these approaches present difficult and complex challenges.

### BRIEF DESCRIPTION OF THE DRAWINGS

The described embodiments are to be read in conjunction with the accompanying drawings, wherein:

FIG. 1 is a block diagram illustrating an example wireless communication device within which the various features of the described embodiments can be advantageously implemented, according to one embodiment;

FIG. 2 provides a block diagram representation of a structural configuration of transceiver module 130 comprising a power amplifier that utilizes an envelope (ET) tracking mechanism, according to one embodiment;

FIG. 3 is a block diagram illustrating an embodiment of Transceiver Module 130 comprising (a) a radio frequency integrated circuit (RFIC) that provides envelope tracking to enable shaping of an amplifier supply voltage and (b) a power amplifier that is powered using the shaped supply voltage;

FIG. 4A illustrates a waveform of RFIC envelope gain plotted against RF drive level, according to one embodiment;

FIG. 4B illustrates a waveform of a power amplifier (PA) envelope gain plotted against RF drive level, according to one embodiment;

FIG. 5 depicts saturation waveforms for a power amplifier and a gain adjustment waveform based on transceiver drive level, according to one embodiment; and

FIG. 6 is a flow chart illustrating one embodiment of a method for providing within a wireless communication device enhanced gain associated with a propagation path that includes a power amplifier that is powered by an ET supply voltage.

### DETAILED DESCRIPTION

The illustrative embodiments provide a method and system for improving the gain of a propagation path of a radio frequency (RF) signal while utilizing an envelope tracking (ET) mechanism to provide power to a power amplifier within the propagation path. An envelope tracking (ET) controller either detects or generates, using the ET mechanism, an RF envelope of the RF signal being propagated towards the power amplifier. The ET controller applies envelope pre-distortion to the RF signal which results in a decreasing gain across a propagation path of the RF signal at high transceiver drive levels. The ET controller initiates a function for shaping the supply voltage of the power amplifier by selecting a shaping table. The selected shaping table provides a specific level of increasing amplifier gain at a higher signal drive level. The ET controller shapes the supply voltage for the power amplifier by adjusting values corresponding to the detected RF envelope. As a result, the ET controller enables RF signals to be propagated from the transceiver to an output port of the power amplifier across high and low transceiver drive levels with net constant gain.

In the following detailed description of exemplary embodiments of the disclosure, specific exemplary embodiments in which the various aspects of the disclosure may be practiced are described in sufficient detail to enable those skilled in the art to practice the invention, and it is to be understood that other embodiments may be utilized and that logical, architectural, programmatic, mechanical, electrical and other changes may be made without departing from the spirit or scope of the present disclosure. The following detailed description is, therefore, not to be taken in a limiting sense, and the scope of the present disclosure is defined by the appended claims and equivalents thereof.

Within the descriptions of the different views of the figures, similar elements are provided similar names and reference numerals as those of the previous figure(s). The specific numerals assigned to the elements are provided solely to aid in the description and are not meant to imply any limitations (structural or functional or otherwise) on the described embodiment.

It is understood that the use of specific component, device and/or parameter names, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that terms is utilized.

As further described below, implementation of the functional features of the disclosure described herein is provided within processing devices and/or structures and can involve use of a combination of hardware, firmware, as well as several software-level constructs (e.g., program code and/or program instructions and/or pseudo-code) that execute to provide a specific utility for the device or a specific functional logic. The presented figures illustrate both hardware components and software and/or logic components.

Those of ordinary skill in the art will appreciate that the hardware components and basic configurations depicted in the figures may vary. The illustrative components are not intended to be exhaustive, but rather are representative to highlight essential components that are utilized to implement aspects of the described embodiments. For example, other devices/components may be used in addition to or in place of the hardware and/or firmware depicted. The depicted example is not meant to imply architectural or other limitations with respect to the presently described embodiments and/or the general invention.

The description of the illustrative embodiments can be read in conjunction with the accompanying figures. It will be appreciated that for simplicity and clarity of illustration, elements illustrated in the figures have not necessarily been drawn to scale. For example, the dimensions of some of the elements are exaggerated relative to other elements. Embodiments incorporating teachings of the present disclosure are shown and described with respect to the figures presented herein.

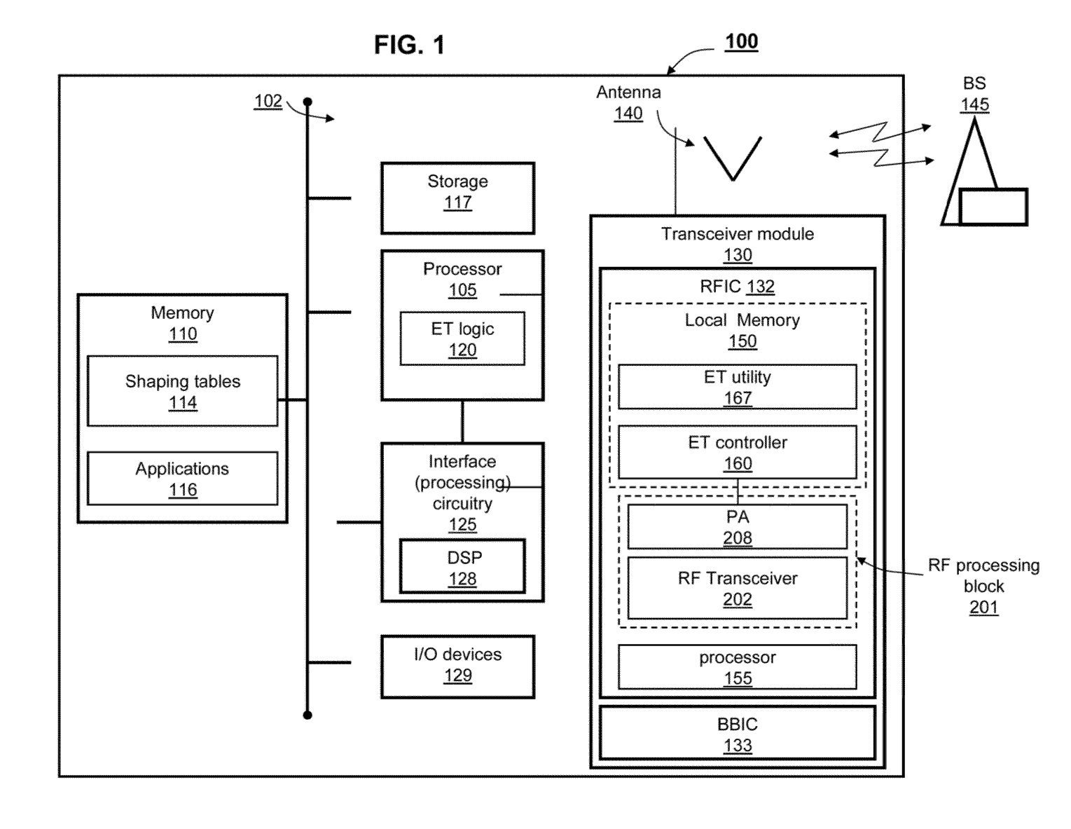

With specific reference now to FIG. 1, there is depicted a block diagram of an example wireless communication device 100, within which the functional aspects of the described embodiments may be implemented. Wireless communication device 100 represents a device that is adapted to transmit and receive electromagnetic signals over an air interface via uplink and/or downlink channels between the wireless communication device 100 and communication network equipment (e.g., base-station 145) utilizing a plurality of different communication standards, such as Global System for Mobile Communications (GSM) Code Division Multiple Access (CDMA), Orthogonal Frequency Division Multiple Access (OFDMA), Long Term Evolution (LTE) and similar systems. In one or more embodiments, the wireless communication device can be a mobile cellular device/phone or smartphone, or laptop, netbook or a tablet computing device, or other types of communications devices. Wireless communication device 100 comprises processor 105 and interface circuitry 125, which are connected to memory component 110 via signal bus 102. Also illustrated in wireless communication device 100 is storage 117. Interface circuitry 125 includes digital signal processor (DSP) 128. Wireless communication device 100 also comprises input/output (I/O) devices 129. Wireless communication device 100 also includes a transceiver module 130 for sending and receiving communication signals. In at least some embodiments, the sending and receiving of communication signals occur wirelessly and are facilitated by one or more antennas 140 coupled to the transceiver module 130. The number of antennas can vary from device to device, ranging from a single antenna to two or more antennas, and the presentation within wireless communication device 100 of one antenna 140 is merely for illustration.

Wireless communication device 100 is able to wirelessly communicate to base-station 145 via antenna 140. Base station 145 can be any one of a number of different types of network stations and/or antennas associated with the infrastructure of the wireless network and configured to support uplink and downlink communication via one or more of the wireless communication protocols, as known by those skilled in the art.

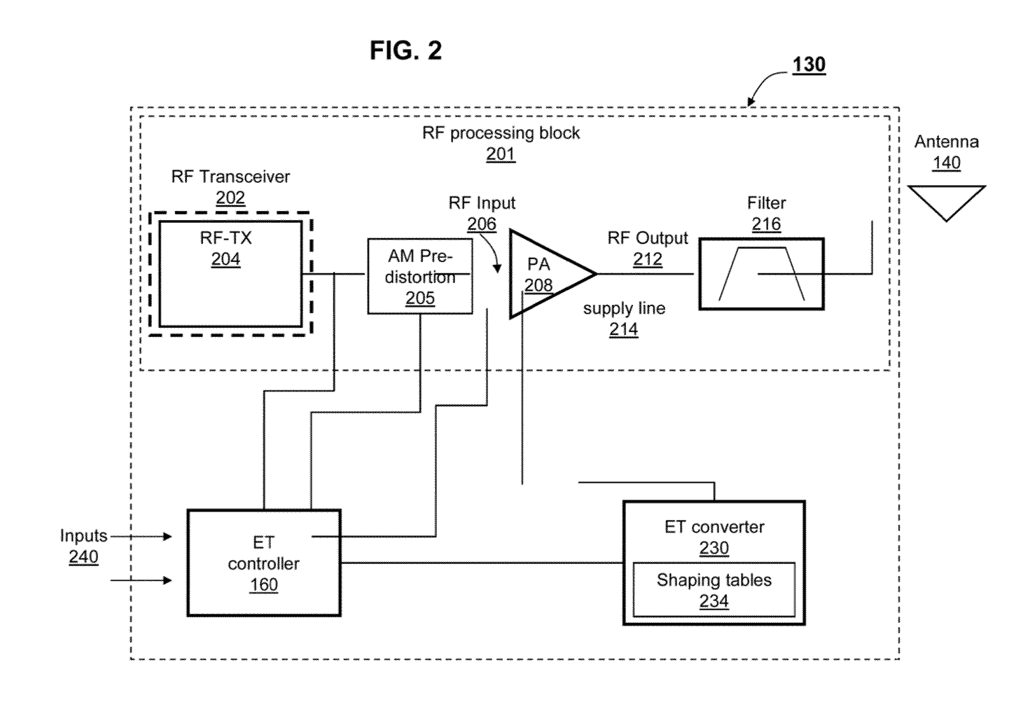

Transceiver module 130 comprises baseband integrated circuit (BBIC) 133 and radio frequency integrated circuit (RFIC) 132. In one embodiment, RFIC 132 comprises RF transceiver 202, local memory 150, envelope tracking (ET) utility 167, processor 155 and ET controller 160. In an alternate embodiment, at least one of the components indicated as being included within RFIC 132 can be located outside of RFIC 132, within transceiver module 130. Transceiver module 130 also comprises RF processing block 201. RF processing block 201 comprises power amplifier 208, transceiver or modulator 202, and other processing block components shown in FIG. 2. In one embodiment, transceiver module 130 also includes local processor 155, which can be described as a digital signal processor (DSP). According to one aspect of the disclosure, local memory/storage 150 includes therein firmware, such as ET utility 167, which supports the various processing functions of transceiver module 130. The structural makeup of transceiver module 130 is described in greater detail in FIG. 2.

In addition to the above described hardware components of wireless communication device 100, various features of the invention may be completed or supported via software (or firmware) code and/or logic stored within at least one of memory 110 and local memory 150, and respectively executed by DSP 128, processor 105, or local processor 155 of transceiver module 130. Thus, for example, illustrated within memory 110 and/or local memory 150 are a number of software/firmware/logic components/modules, including shaping tables 114, applications 116 and ET utility 167. In one embodiment, processor 105 executes ET utility 167 to provide ET logic 120.

The various components within wireless communication device 100 can be electrically and/or communicatively coupled together as illustrated in FIG. 1. As utilized herein, the term “communicatively coupled” means that information signals are transmissible through various interconnections between the components. The interconnections between the components can be direct interconnections that include conductive transmission media, or may be indirect interconnections that include one or more intermediate electrical components. Although certain direct interconnections are illustrated in FIG. 1, it is to be understood that more, fewer or different interconnections may be present in other embodiments.

FIG. 2 provides a block diagram representation of a structural configuration of transceiver module 130 comprising a power amplifier that utilizes an envelope (ET) tracking mechanism, according to one embodiment. Transceiver module 130 comprises radio frequency (RF) processing block 201, envelope tracking (ET) controller 160 and ET converter 230. ET controller 160 manages an operation of ET converter 230. In one embodiment, ET controller includes the functionality of a direct power amplifier controller and, as a result, controls operation of power amplifier 208. The direct power amplifier controller functionality can include coarse gain setting functionality which can be achieved by control of RF switches for routing of RF signals among the individual amplifier stages within power amplifier 208, and bias settings for the individual amplifier stages within power amplifier 208. RF processing block 201 comprises RF transceiver or digital modulator 202, which includes RF transmitter (TX) 204 and an RF receiver (RX) (not shown). In one embodiment, RF transceiver 202 and ET controller 160 constitute RFIC 132 (not shown). RF processing block 201 also comprises AM pre-distortion module 205, power amplifier (PA) 208 and filter 216. Filter 216 is coupled to an output port of power amplifier 208. Filter 216 is communicatively coupled to antenna 140. Also shown within RF processing block 201 is RF Input 206 and RF Output 212, which respectively represent the input signal and the output signal of PA 208. Power is provided to PA 208 via supply line 214 from ET converter 230.

ET controller 160 is coupled to at least one output port of transceiver 202 in order to track the RF envelope of a propagating RF signal. In addition, ET controller 160 is also coupled to ET converter 230. In one implementation, ET converter 230 includes shaping tables 234. However, in another implementation, ET controller 160 receives inputs 240 which include shaping tables 114 (FIG. 1).

ET controller 160 improves the gain of a propagation path of an RF signal by utilizing envelope pre-distortion and supply voltage shaping. In transceiver module 130, transceiver 202 propagates an RF signal and ET controller 160 activates an envelope tracking (ET) mechanism to detect or generate an RF envelope of the RF signal propagating along the propagation path. In one embodiment, ET controller 160 detects the In-phase (I) and Quadrature (Q) RF signal components or coordinates, which collectively provide a rectangular coordinate representation of the RF signal. ET controller 160 converts the I and Q signal components to polar components having amplitude and phase. The amplitude of the polar coordinate representation provides the RF signal envelope. In one implementation, ET controller 160 utilizes a Coordinate Rotation Digital Computer (CORDIC) to perform the conversion from rectangular to polar coordinates.

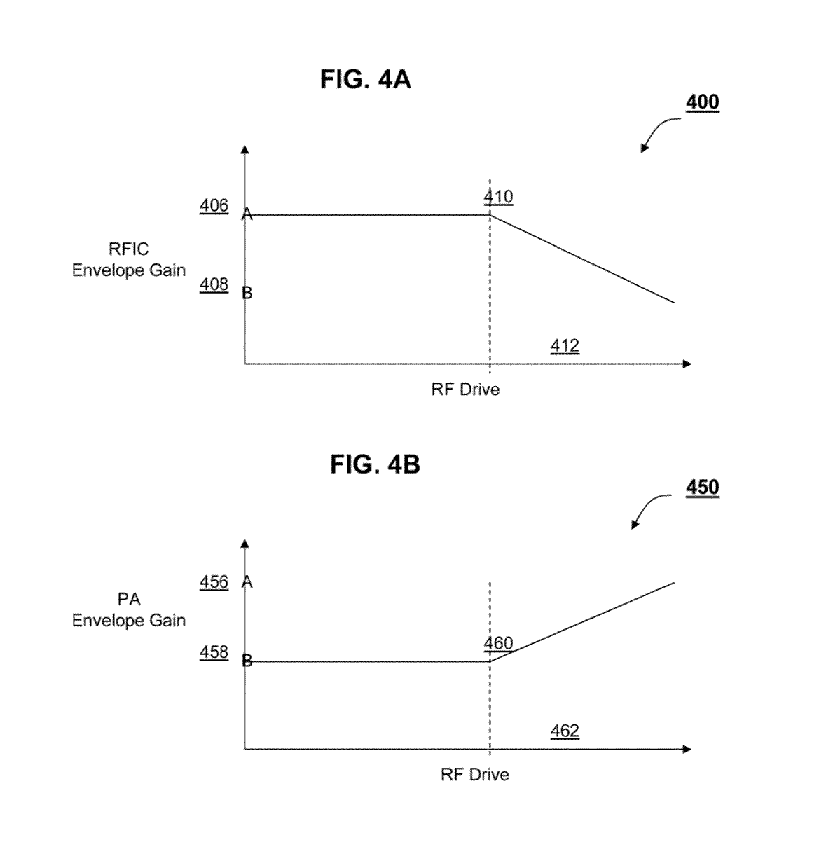

As described above, ET controller 160 either detects or generates, using the ET mechanism, an RF envelope of the RF signal being propagated towards power amplifier 208. Furthermore, ET controller 160 utilizes AM pre-distortion module 205 to apply envelope pre-distortion to the RF signal to appropriately adjust the amplitude of the RF signal envelope to compensate for the increasing gain of power amplifier 208 at high transceiver drive levels. Adjusting the amplitude of the RF signal envelope results in a decreasing RF signal gain (FIG. 4A) at high transceiver drive levels or RF drive levels. ET controller 160 shapes the supply voltage of power amplifier 208 by selecting a shaping table that can provide a specific level of increasing amplifier gain (FIG. 4B) at high transceiver drive levels. The increasing gain of power amplifier 208 is substantially compensated for by the decreasing RF envelope gain and enables the RF signal to be transmitted with the proper RF signal envelope.

ET controller 160 shapes the supply voltage for power amplifier 208 by adjusting amplitude values corresponding to the detected RF envelope in order to provide a specific level of increasing amplifier gain at high transceiver drive levels. By shaping the supply voltage and applying envelope pre-distortion, ET controller 160 enables RF signals to be propagated from transceiver 202 to an output port of power amplifier 208 across high and low transceiver drive levels, with a net constant gain. By controlling the ET converter 230 and AM pre-distortion 205 to respectively provide the decreasing RFIC envelope gain and the increasing amplifier envelope gain at high drive levels, envelope tracking of power amplifier 208 can be implemented to benefit amplifier efficiency, without causing a gain reduction in power amplifier 208, which would necessitate a higher power of RF Input 206.

In one embodiment, ET controller 160 initiates the shaping function by accessing a stored data structure having a number of shaping tables that can be utilized to shape the supply voltage to power amplifier 208. ET controller 160 selects, from among the number of shaping tables, a shaping table that provides a specific or pre-determined level of increasing amplifier gain at higher signal drive levels. ET controller 160 adjusts values corresponding to the detected RF envelope using the selected shaping table to provide adjusted envelope values. These adjusted envelope values are utilized to modulate a supply voltage (e.g., VCC 317) to provide a shaped supply voltage to power amplifier 208. With the shaped supply voltage, ET controller 160 provides an increasing amplifier gain at signal drive levels that exceed a threshold drive level. ET controller 160 shapes the supply voltage to achieve constant gain of power amplifier 208 across low signal drive levels and increasing power amplifier gain across higher signal drive levels. Specifically, ET controller 160 adjusts the RF signal envelope to provide an increasing power amplifier gain at high signal drive levels and relatively lower, constant gain at lower signal drive levels. The lower, constant gain is associated with a lower supply voltage to power amplifier 208, and the lower supply voltage is associated with a smaller magnitude of the RF signal envelope.

ET controller 160 initiates envelope pre-distortion by accessing a stored data structure having pre-determined values for a distorted RF signal envelope expected at an output port of power amplifier 208. The distorted RF signal is identified by at least one of an operating frequency band and a communication mode such as an operating condition or environment. ET controller 160 determines using LUT 306 or calculates values that compensate for (a) the predetermined values associated with the distorted RF signal envelope expected in order to maintain appropriate RF signal envelope amplitudes and (b) an increasing amplifier gain at high signal drive levels. ET controller 160 provides pre-distortion of the RF signal envelope using the calculated values, following digital modulation of a corresponding signal envelope. In one embodiment, ET controller 160 applies envelope pre-distortion by providing, via AM pre-distortion module 205: (a) a first, lower amplitude of the RF signal envelope when a magnitude of the RF envelope is large and the power amplifier gain is high; and (b) a second, higher amplitude of the RF envelope when the magnitude of the RF envelope is small and the power amplifier gain is low. By applying envelope pre-distortion using AM pre-distortion module 205, ET controller 160 determines an amplitude adjustment to compensate for an expected power amplifier output distortion and avoids using a feedback mechanism to adjust for a detected power amplifier output distortion. As a result, ET controller 160 enables power amplifier 208 to maintain a pre-established high level of efficiency.

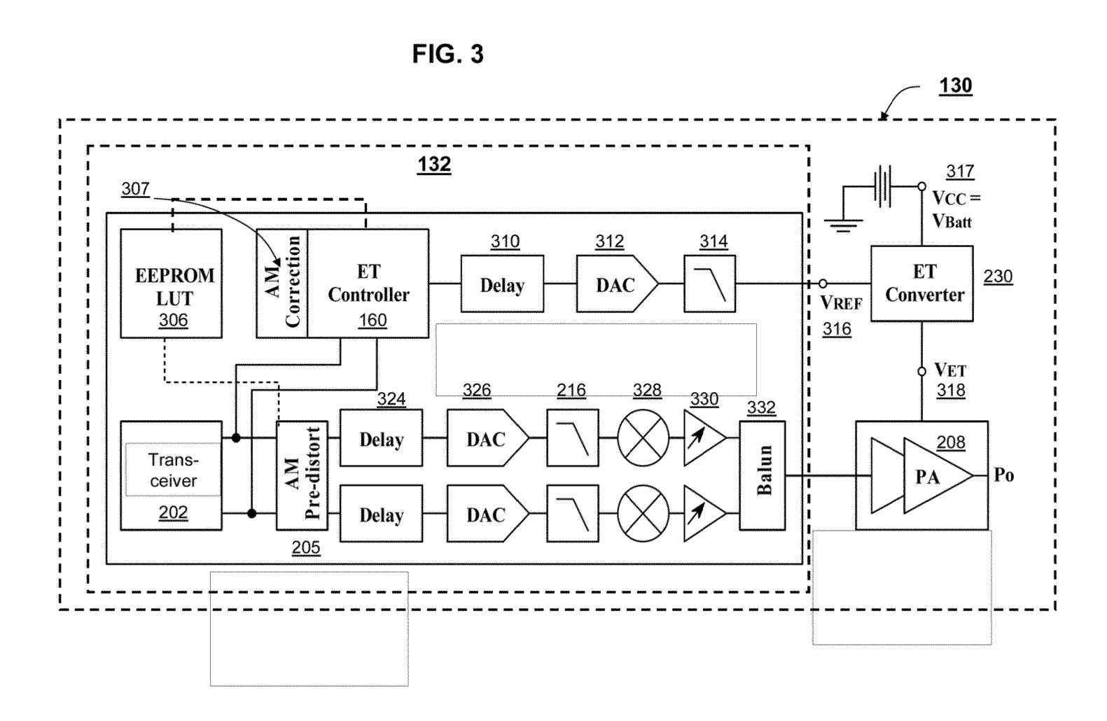

FIG. 3 is a block diagram illustrating an embodiment of Transceiver Module 130 comprising (a) a radio frequency integrated circuit (RFIC) that provides envelope tracking to enable shaping of an amplifier supply voltage and (b) a power amplifier that is powered using the shaped supply voltage, according to one embodiment. Transceiver module 130 comprises RFIC 132, ET converter 230 and power amplifier 208. ET converter 230 and power amplifier 208 are respectively coupled to RFIC 132. RFIC 132 comprises RF transceiver 202 and amplitude modulation (AM) pre-distortion component 205 coupled to the outputs of digital modulator 202. RFIC 132 also comprises delay components 324 and digital to analog converter (DAC) components 326. Also included in RFIC 132 are low-pass filters 216 and multiplier components 328. In addition, RFIC 132 comprises power pre-amplifier components 330 coupled to respective output ports of multiplier components 328. RFIC 132 includes Balun 332 which functions as a transmission line transformer. The name “Balun” is derived from a corresponding device function for converting between differential, or “balanced”, signals and single-ended, or “unbalanced” signals. Balun 332 is coupled to the input port of power amplifier 208.

RFIC 132 also comprises envelope tracking (ET) controller 160 which is also coupled to at least one output port of digital modulator 202. RFIC 132 also comprises look up table (LUT) 306. In one implementation, LUT 306 is an Electrically Erasable Programmable Read-Only Memory (EEPROM) LUT. In one implementation, LUT 306 is coupled to both AM pre-distorter 205 and ET controller 160 to facilitate AM pre-distortion and PA supply voltage shaping, respectively. In one embodiment, ET controller 160 includes amplitude modulation (AM) correction module 307 which is utilized by ET controller 160 to retrieve the appropriate pre-distortion data or files from LUT 306. ET controller 160 is able to retrieve from LUT 306 AM pre-distortion values based on at least one of: (a) amplifier gain; (b) offset; (c) RF signal delay; and (d) power amplifier temperature and/or associated component temperature. In one embodiment, ET controller 160 initiates supply voltage shaping by retrieving shaping tables from LUT 306. The shaped supply voltage is provided to power amplifier 208 via ET converter 230. Delay component 310 is coupled to an output port of ET controller 160 and provides specific functionality described in the below paragraphs. Coupled to an output port of delay component 310 is DAC 312 which is coupled to low-pass filter 314. Low-pass filter 314 provides V_{REF} 316 as an output voltage. In one embodiment, V_{REF} 316 represents the adjusted RF signal envelope. In another embodiment, V_{REF} 316 represents the detected or generated RF signal envelope. RFIC 132 also comprises ET converter 230 which is coupled to an output of low-pass filter 314 and which receives V_{REF} 316 as an input voltage which ET converter 230 uses to generate the power amplifier supply voltage. Supply power V_{cc} is provided to ET converter 230 by source V_{BATT} 317. ET converter 230 provides envelope modulated and voltage shaped supply power V_{ET} 318 to power amplifier 208. In shaping the power amplifier supply voltage, ET controller 160 adjusts amplitude values corresponding to the detected RF envelope to generate V_{REF} 316 and modulates V_{cc} 317 (using ET converter 230) with V_{REF} 316 to generate supply power V_{ET} 318. By providing a shaped supply voltage (i.e., V_{ET} 318) to power amplifier 208, ET controller 160 provides an increasing gain of power amplifier 208 at higher signal drive levels.

Within the RF signal propagation path, digital modulator 202 provides a digital complex baseband signal pair which is received by AM pre-distortion component 205. AM pre-distortion component 205 provides values to compensate the signals for distortion expected at the output port of power amplifier 208. In one embodiment, the RF input signal envelope is detected and the detected signal envelope is used to determine the appropriate pre-distortion values. ET controller 160 applies an envelope pre-distortion, via AM pre-distortion component 205, to the digital complex baseband signal to compensate the signal amplitude for distortion that is expected at the output of power amplifier 208. In an embodiment, the AM pre-distortion component 205 employs the values using complex arithmetic to adjust the envelope or amplitude of the digital complex baseband signal pair. The applied envelope pre-distortion provides a decreasing RF envelope gain at higher signal drive levels of RF transceiver 202.

Delay components 324 facilitate timing synchronization between propagation of an RF signal to power amplifier 208 and provision of an ET supply voltage to power amplifier 208. The pre-distorted and delayed digital complex baseband signal pair is passed to DACs 326 for converting from digital to analog to form analog baseband signals. The analog baseband signals(s) are low-pass filtered to remove harmonic distortion using filters 216 to form a filtered analog baseband signal. Modulation of the filtered analog baseband signals onto an RF carrier is achieved using multiplier components 328. Multipliers 328 are used to mix the baseband signals with in-phase and quadrature RF carrier signals (not shown) to generate a modulated RF carrier in differential form. Amplifiers 330 provide an additional power gain stage to form an amplified modulated RF signal in differential form. Balun 332 receives the amplified modulated RF signal and provides a corresponding single-ended RF signal to power amplifier 208. In an embodiment, Balun 332 performs one or more balancing functions associated with differences in transmission line characteristics between the respective differential RF signals.

Power amplifier 208 receives as an input signal the corresponding RF signal in synchronization with the envelope tracked supply voltage associated with the RF input signal envelope. The increasing amplifier gain provided by ET converter 230 is substantially compensated for by the decreasing RF envelope gain provided by the applied envelope pre-distortion. Applying envelope distortion within the RF signal propagation path and shaping a power amplifier supply voltage by adjusting values corresponding to the detected RF envelope collectively provide a net constant gain across lower and higher transceiver drive levels of the RF signal propagating along the propagation path.

FIG. 4A illustrates a waveform of RFIC envelope gain plotted against RF drive level, according to one embodiment. Plot 400 comprises a vertical axis representing RFIC envelope gain, a horizontal axis representing RF drive level and waveform 410. In one embodiment, the RF drive level is the amplitude of the RF signal provided by RF transceiver 202 and is also referred to herein as the transceiver drive level. Gain “A” 406 and gain “B” 408 are gain values illustrated on the vertical or RFIC envelope gain axis. Threshold drive level 412 is illustrated as a vertical dashed line perpendicular to the horizontal or RF drive level axis. At RF drive levels that are greater than the threshold drive level (indicated by threshold drive level 412), waveform 410 indicates that the RFIC envelope gain is decreasing as the drive level increases. When the RF drive level is less than the threshold drive level, the RFIC envelope gain is equal to A. The gain value “B” represents the PA envelope gain described in plot 450 (FIG. 4B) and is indicated in plot 400 to provide a relative gain indication for an implementation in which the RFIC envelope gain and the PA envelope gain differ. The RFIC envelope gain is measured across an RF propagation path between an output port of digital modulator 202 and an input port of power amplifier 208. As described above (FIG. 3), ET controller 160 applies an envelope pre-distortion to a propagating RF signal to compensate for distortion that is expected at an output of power amplifier 208. The applied envelope pre-distortion provides the decreasing RF envelope gain at higher signal drive levels of RF transceiver 202.

FIG. 4B illustrates a waveform of a power amplifier (PA) envelope gain plotted against RF drive level, according to one embodiment. Plot 450 comprises a vertical axis representing PA envelope gain, a horizontal axis representing RF drive level and waveform 460. Gain “A” 456 and gain “B” 458 are gain values illustrated on the vertical or PA envelope gain axis. Threshold drive level 462 is illustrated as a vertical dashed line perpendicular to the horizontal or RF drive level axis. At RF drive levels that are greater than the threshold drive level (indicated by threshold drive level 462), waveform 460 indicates that the PA envelope gain is increasing as the drive level increases. When the RF drive level is less than the threshold drive level, the RFIC envelope gain is equal to B. The gain value “A” represents the RFIC envelope gain described in plot 400 (FIG. 4A) and is indicated in plot 450 to provide a relative gain indication for an implementation in which the RFIC envelope gain and the PA envelope gain differ. The PA envelope gain is a measure of an instantaneous gain of power amplifier 208 provided by a ratio of the output RF signal envelope and the input RF signal envelope. As described above (FIG. 3), ET controller 160 shapes the supply voltage for power amplifier 208 by adjusting values corresponding to the detected RF envelope in order to provide the specific level of increasing amplifier gain at high transceiver drive levels (i.e., greater than the threshold drive level).

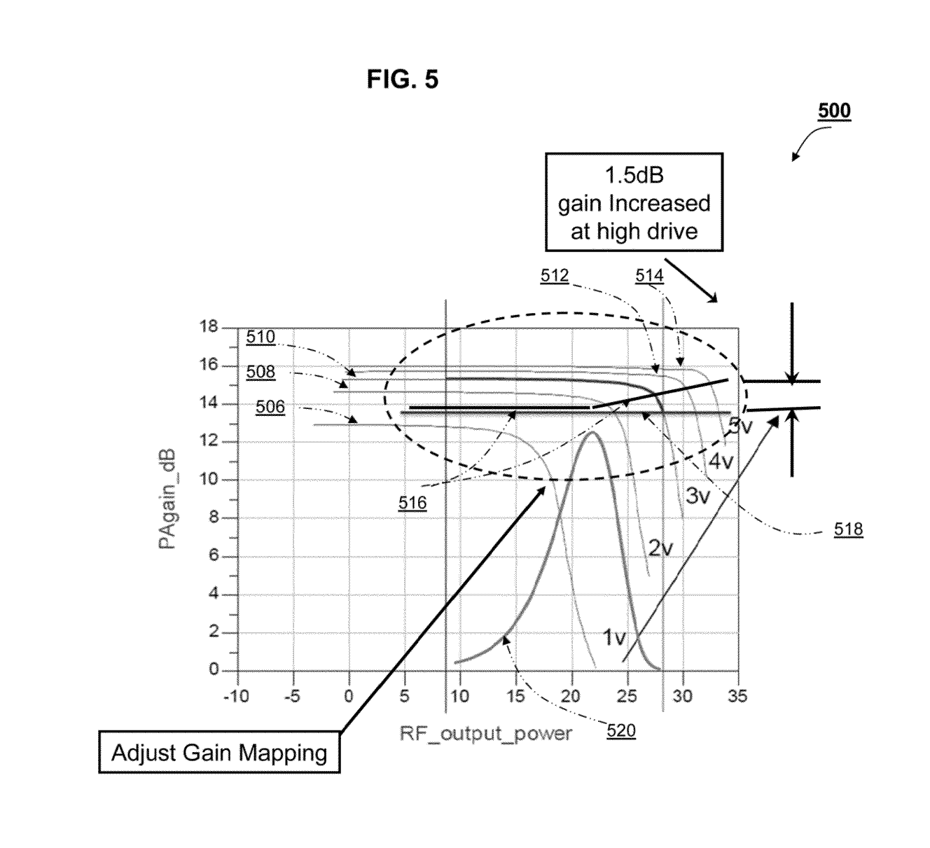

FIG. 5 depicts saturation waveforms for a power amplifier and a gain adjustment waveform based on transceiver drive level, according to one embodiment. Plot 500 comprises a vertical axis representing power amplifier gain and labeled as “PAgain_dB”. In addition, plot 500 comprises horizontal axis representing RF output power and labeled as “RF_output_power”. Plot 500 provides five saturation waveforms corresponding to five different biasing supply voltages. In particular, first saturation waveform 506 corresponds to a 1 volt biasing supply voltage, second saturation waveform 508 corresponds to a 2 volt biasing supply voltage, third saturation waveform 510 corresponds to a 3 volt biasing supply voltage, fourth saturation waveform 512 corresponds to a 4 volt biasing supply voltage and fifth saturation waveform 514 corresponds to a 5 volt biasing supply voltage. Plot 500 also comprises enhanced PA envelope gain waveform 516 and flat gain waveform 518. Additionally, plot 500 comprises probability density function waveform 520.

Enhanced PA envelope gain waveform 516 represents the impact (measured relative to flat gain waveform 518) that applying a shaping function to the supply voltage has on the PA envelope gain. Compared with waveform 460 of plot 450 (FIG. 4B), enhanced PA envelope gain waveform 516 similarly depicts an increasing PA envelope gain at higher drive levels. In one implementation, the shaping function is provided by the use of shaping tables. From the multiple saturation waveforms of plot 500, it can be inferred that if the shaping function associated with the enhanced PA envelope gain is de-activated the gain of the PA varies with RF drive level on PA supply voltage. However, a shaping table is used to shape the supply voltage with RF drive level to achieve a net constant gain of the RF signal propagating along the propagation path across a specific range of RF drive levels. In order to achieve the net flat gain of the RF signal across the propagation path, the supply voltage is “shaped” to provide a constant gain of the PA envelope at lower drive levels and the increasing gain of the PA envelope at higher drive levels. The increasing gain of the PA envelope at higher drive levels compensates for a decreasing RF envelope gain (at higher signal drive levels) that is provided by applying an envelope pre-distortion to the RF signal to compensate for distortion that is expected at an output of power amplifier 208.

Probability density function waveform 520 indicates that the operating time of envelope-tracking power amplifier (e.g., power amplifier 208) is spent primarily with the power amplifier using a relatively low supply voltage, with only occasional high-voltage excursions on high-power peaks. Based on the statistics that can be obtained using the probability density function, the amplifier's matching can be optimized to achieve the best efficiency by using the target peak- to average-power-ratio signals rather than simply designing for best efficiency at peak power and maximum supply voltage, as would be the case for a fixed-supply power amplifier. Designers can alter the amplifier's matching to increase efficiency around the peak of the signal's probability-density function, even if this necessitates a slight compromise in the peak power efficiency.

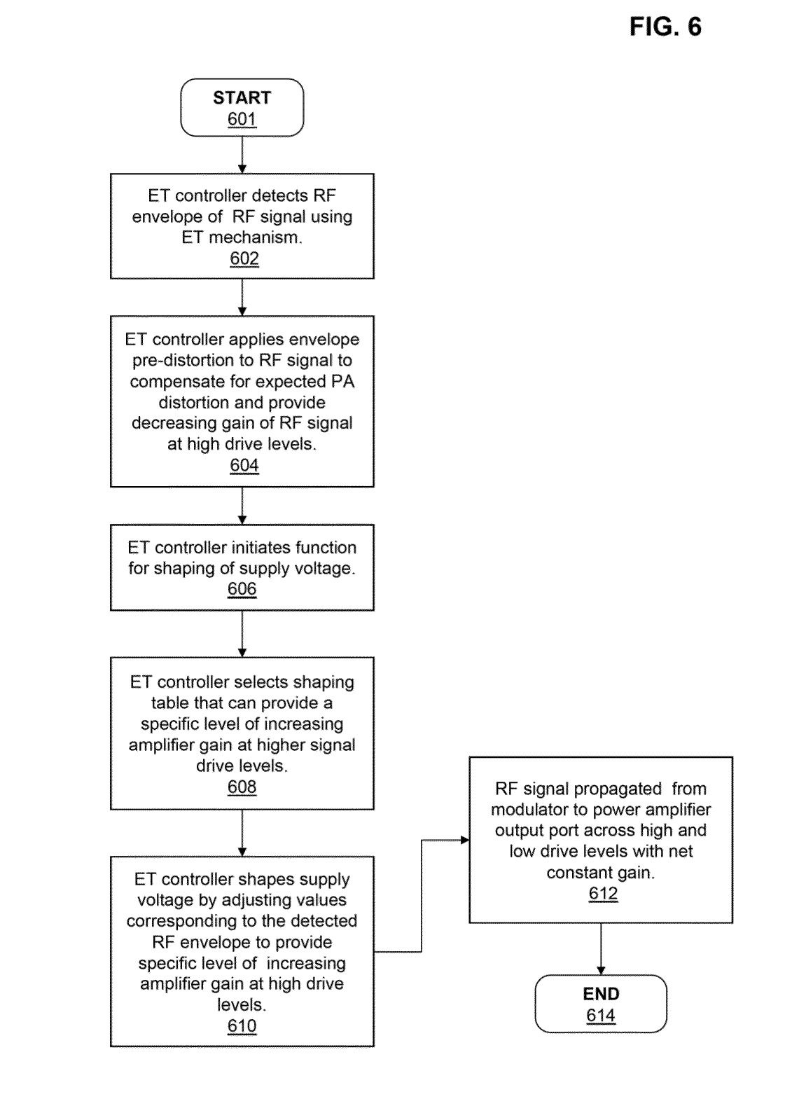

FIG. 6 is a flow chart illustrating an embodiment of the method by which the above processes of the illustrative embodiments can be implemented. Specifically, FIG. 6 illustrates one embodiment of a method for providing enhanced gain associated with a propagation path that includes a power amplifier that is powered by an ET supply voltage. Although the method illustrated by FIG. 6 may be described with reference to components and functionality illustrated by and described in reference to FIGS. 1-5, it should be understood that this is merely for convenience and alternative components and/or configurations thereof can be employed when implementing the method. Certain portions of the methods may be completed by ET utility 167 executing on one or more processors (processor 105 or DSP 128) within wireless communication device 100 (FIG. 1), or a processing unit or ET controller 160 of RFIC 132 (FIG. 1). The executed processes then control specific operations of or on RFIC 132. For simplicity in describing the method, all method processes are described from the perspective of RFIC 132 and specifically ET controller 160.

The method of FIG. 6 begins at initiator block 601 and proceeds to block 602 at which ET controller 160 detects RF envelope of RF signal using ET mechanism. In particular, ET controller 160 tracks an amplitude of an RF signal being propagated to power amplifier 208. At block 604, ET controller 160 applies envelope pre-distortion to the RF signal to (a) compensate for distortion that is expected at an output of the power amplifier and (b) provide a decreasing RF envelope gain across a propagation path of the RF signal at high transceiver drive levels. At block 606, ET controller 160 initiates or activates a function for shaping the supply voltage of power amplifier 208. At block 608, ET controller 160 selects a shaping table that provides a specific level of increasing amplifier gain at higher signal drive levels. At block 610, ET controller 160 shapes the supply voltage for power amplifier 208 by adjusting values corresponding to the detected RF envelope in order to provide increasing amplifier gain at high transceiver drive levels. At block 612, ET controller 160 enables RF signals to be propagated from RF transceiver 202 to an output port of power amplifier 208 across high and low transceiver drive levels with net constant gain. The process ends at block 614.

The flowchart and block diagrams in the various figures presented and described herein illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Thus, while the method processes are described and illustrated in a particular sequence, use of a specific sequence of processes is not meant to imply any limitations on the disclosure. Changes may be made with regards to the sequence of processes without departing from the spirit or scope of the present disclosure. Use of a particular sequence is therefore, not to be taken in a limiting sense, and the scope of the present disclosure extends to the appended claims and equivalents thereof.

In some implementations, certain processes of the methods are combined, performed simultaneously or in a different order, or perhaps omitted, without deviating from the spirit and scope of the disclosure. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular system, device or component thereof to the teachings of the disclosure without departing from the essential scope thereof. Therefore, it is intended that the disclosure not be limited to the particular embodiments disclosed for carrying out this disclosure, but that the disclosure will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

1. A method for providing gain adjustment in a power amplifier, the method comprising:
propagating a radio frequency (RF) signal;
initiating an envelope tracking (ET) mechanism to detect an RF envelope of the RF signal propagating along a propagation path that includes the power amplifier;
applying to the RF signal an envelope pre-distortion to (a) compensate for distortion that is expected at an output of the power amplifier and (b) provide a decreasing RF envelope gain at higher signal drive levels of a corresponding transceiver; and
adjusting amplitude values of the detected RF envelope to shape a supply voltage of the power amplifier in order to provide at higher signal drive levels an increasing amplifier gain that is substantially compensated for by said decreasing RF envelope gain and enables the RF signal propagating along the propagation path to the output of the power amplifier to achieve a net constant gain.

2. The method of claim 1, wherein said adjusting further comprises:
accessing a stored data structure having a number of shaping tables that can be utilized to shape the supply voltage to the power amplifier;
selecting a shaping table from among the number of shaping tables, wherein the selected shaping table is one that provides a specific level of increasing amplifier gain at higher signal drive levels; and
adjusting amplitude values of the detected RF envelope using the selected shaping table in order to provide increasing amplifier gain at signal drive levels that exceed a threshold drive level.

3. The method of claim 2, further comprising:
shaping the supply voltage to achieve constant gain across low signal drive levels and increasing gain across higher signal drive levels, wherein said shaping the supply voltage provides a pre-determined gain.

4. The method of claim 2, further comprising:
adjusting the RF signal envelope to provide an increasing power amplifier gain at high signal drive levels and a constant gain at low signal drive levels, wherein said constant gain is associated with a lower supply voltage to the power amplifier, and wherein said lower supply voltage is associated with a smaller magnitude of the RF signal envelope.

5. The method of claim 1, wherein said applying the envelope pre-distortion further comprises:
accessing a stored data structure having pre-determined values for a distorted RF signal envelope expected at an output port of the power amplifier, wherein said distorted RF signal is identified by at least one of an operating frequency band and a communication mode;
calculating values that compensate for (a) the predetermined values associated with the distorted RF signal envelope expected in order to maintain appropriate RF signal envelope amplitudes and (b) an increasing amplifier gain at high signal drive levels; and
providing pre-distortion of the RF signal envelope using the calculated values, following digital modulation of a corresponding signal envelope.

6. The method of claim 5, wherein said applying the envelope pre-distortion further comprises:
providing via an amplitude pre-distortion component: (a) a first, lower amplitude of an RF signal envelope when a magnitude of the RF envelope is large and the power amplifier gain is high; and (b) a second, higher amplitude of the RF signal envelope when the magnitude of the RF envelope is small and the power amplifier gain is low.

7. The method of claim 1, wherein said applying the envelope pre-distortion determines an amplitude adjustment to compensate for an expected power amplifier output distortion and avoids using a feedback mechanism to adjust for a detected power amplifier output distortion, and enables the power amplifier to maintain a pre-established high level of efficiency.

8. A radio frequency integrated circuit (RFIC) comprising:
at least one transceiver;
a power amplifier;
an envelope tracking (ET) supply module;
a power amplifier controller coupled to the ET supply module and which:
propagates a radio frequency (RF) signal;
initiates an envelope tracking (ET) mechanism to detect an RF envelope of the RF signal propagating along a propagation path that includes the power amplifier;
applies to the RF signal an envelope pre-distortion to (a) compensate for distortion that is expected at an output of the power amplifier and (b) provide a decreasing RF envelope gain at higher signal drive levels of a corresponding transceiver; and
adjusts amplitude values of the detected RF envelope to shape a supply voltage of the power amplifier in order to provide at higher signal drive levels an increasing amplifier gain that is substantially compensated for by said decreasing RF envelope gain and enables the RF signal propagating along the propagation path to the output of the power amplifier to achieve a net constant gain.

9. The RFIC of claim 8, wherein the power amplifier controller:
accesses a stored data structure having a number of shaping tables that can be utilized to shape the supply voltage to the power amplifier;
selects a shaping table from among the number of shaping tables, wherein the selected shaping table is one that provides a specific level of increasing amplifier gain at higher signal drive levels; and
adjusts amplitude values of the detected RF envelope using the selected shaping table in order to provide increasing amplifier gain at signal drive levels that exceed a threshold drive level.

10. The RFIC of claim 9, wherein the power amplifier controller:
shapes the supply voltage to achieve constant gain across low signal drive levels and increasing gain across higher signal drive levels, wherein shaping the supply voltage provides a pre-determined gain.

11. The RFIC of claim 9, wherein the power amplifier controller:
adjusts the RF signal envelope to provide an increasing power amplifier gain at high signal drive levels and a constant gain at low signal drive levels, wherein said constant gain is associated with a lower supply voltage to the power amplifier, and wherein said lower supply voltage is associated with a smaller magnitude of the RF signal envelope.

12. The RFIC of claim 8, wherein the power amplifier controller:
accesses a stored data structure having pre-determined values for a distorted RF signal envelope expected at an output port of the power amplifier, wherein said distorted RF signal is identified by at least one of an operating frequency band and a communication mode;
calculates values that compensate for (a) the predetermined values associated with the distorted RF signal envelope expected in order to maintain appropriate RF signal envelope amplitudes and (b) an increasing amplifier gain at high signal drive levels;
avoids use of a feedback mechanism to adjust for a detected power amplifier output distortion; and
provides pre-distortion of the RF signal envelope using the calculated values, following digital modulation of a corresponding signal envelope.

13. The RFIC of claim 12, wherein the power amplifier controller:
provides via an amplitude pre-distortion component: (a) a first, lower amplitude of an RF signal envelope when a magnitude of the RF envelope is large and the power amplifier gain is high; and (b) a second, higher amplitude of the RF signal envelope when the magnitude of the RF envelope is small and the power amplifier gain is low.

14. The RFIC of claim 8, wherein the power amplifier controller enables the power amplifier to maintain a pre-established high level of efficiency.

15. A wireless communication device having a radio frequency integrated circuit (RFIC) coupled to at least one antenna and which includes:
at least one processor;
at least one transceiver;
a power amplifier;
an envelope tracking (ET) supply module;
a power amplifier controller coupled to the ET supply module and which:
propagates a radio frequency (RF) signal;
initiates an envelope tracking (ET) mechanism to detect an RF envelope of the RF signal propagating along a propagation path that includes the power amplifier;
applies to the RF signal an envelope pre-distortion to (a) compensate for distortion that is expected at an output of the power amplifier and (b) provide a decreasing RF envelope gain at higher signal drive levels of a corresponding transceiver; and
adjusts amplitude values of the detected RF envelope to shape a supply voltage of the power amplifier in order to provide at higher signal drive levels an increasing amplifier gain that is substantially compensated for by said decreasing RF envelope gain and enables the RF signal propagating along the propagation path to the output of the power amplifier to achieve a net constant gain.

16. The wireless communication device of claim 15, wherein the power amplifier controller:
accesses a stored data structure having a number of shaping tables that can be utilized to shape the supply voltage to the power amplifier;
selects a shaping table from among the number of shaping tables, wherein the selected shaping table is one that provides a specific level of increasing amplifier gain at higher signal drive levels; and
adjusts amplitude values of the detected RF envelope using the selected shaping table in order to provide increasing amplifier gain at signal drive levels that exceed a threshold drive level.

17. The wireless communication device of claim 16, wherein the power amplifier controller:
shapes the supply voltage to achieve constant gain across low signal drive levels and increasing gain across higher signal drive levels, wherein shaping the supply voltage provides a pre-determined gain.

18. The wireless communication device of claim 16, wherein the power amplifier controller:
adjusts the RF signal envelope to provide an increasing power amplifier gain at high signal drive levels and a constant gain at low signal drive levels, wherein said constant gain is associated with a lower supply voltage to the power amplifier, and wherein said lower supply voltage is associated with a smaller magnitude of the RF signal envelope.

19. The wireless communication device of claim 15, wherein the power amplifier controller:
accesses a stored data structure having pre-determined values for a distorted RF signal envelope expected at an output port of the power amplifier, wherein said distorted RF signal is identified by at least one of an operating frequency band and a communication mode;
calculates values that compensate for (a) the predetermined values associated with the distorted RF signal envelope expected in order to maintain appropriate RF signal envelope amplitudes and (b) an increasing amplifier gain at high signal drive levels;
avoids use of a feedback mechanism to adjust for a detected power amplifier output distortion; and
provides pre-distortion of the RF signal envelope using the calculated values, following digital modulation of a corresponding signal envelope.

20. The wireless communication device of claim 19, wherein the power amplifier controller:
provides via an amplitude pre-distortion component: (a) a first, lower amplitude of an RF signal envelope when a magnitude of the RF envelope is large and the power amplifier gain is high; and (b) a second, higher amplitude of the RF signal envelope when the magnitude of the RF envelope is small and the power amplifier gain is low; and
enables the power amplifier to maintain a pre-established high level of efficiency.
